(19) United States
(12) Patent Application Publication
(10) Pub. No.: US 2016/0024654 A1
(43) Pub. Date: Jan. 28, 2016

(54) Film Forming Apparatus

(71) Applicant: TOKYO ELECTRON LIMITED, Tokyo (JP)

(72) Inventors: Kohei FUKUSHIMA, Oshu-shi (JP); Yutaka MOTOYAMA, Oshu-shi (JP); Pao-Hwa CHOU, Nirasaki City (JP)

(21) Appl. No.: 14/809,837

(22) Filed: Jul. 27, 2015

(30) Foreign Application Priority Data
Jul. 28, 2014 (JP) 2014-153094
May 7, 2015 (JP) 2015-094907

(51) Int. Cl. C23C 16/455; C23C 16/458

(52) U.S. Cl. CPC C23C 16/45546; C23C 16/45517; C23C 16/45519; C23C 16/45557; C23C 16/4583

(57) ABSTRACT

A film forming apparatus includes a first and second source gas suppliers configured to limitedly supply a source gas only to a first and second substrate areas, respectively, a reaction gas supplier configured to supply a reaction gas to the first substrate area and the second substrate area, a purge gas supplier configured to supply a purge gas for preventing the source gas supplied to one of the first and second substrate areas from being supplied to the other substrate area, a division-purpose substrate held between the first and second substrate areas in a substrate holding part, and a control part configured to output a control signal such that a first cycle including supplying the source gas and the reaction gas to the first substrate area and a second cycle including supplying the source gas and the reaction gas to the second substrate area are each performed plural times.

### CROSS-REFERENCE TO RELATED APPLICATIONS

This application claims the benefit of Japanese Patent Applications Nos. 2014-153094 and 2015-094907, filed on Jul. 28, 2014 and May 7, 2015, respectively, in the Japan Patent Office, the disclosures of which are incorporated herein in their entirety by reference.

### TECHNICAL FIELD

The present disclosure relates to a film forming apparatus for forming a film in a state in which a substrate holding part holding a plurality of substrates in a form of a shelf is disposed in a vertical reaction vessel.

### BACKGROUND

Atomic layer deposition (ALD) is used as a method of forming a film on a substrate such as a semiconductor wafer (hereinafter, referred to as a “wafer”). In the ALD, a gas (source gas) that is a film forming source material is supplied to a surface of a wafer, thereby forming an atomic layer or molecular layer of the source gas adsorbed onto the surface of the wafer, and a reaction product is then generated by supplying a reaction gas for oxidizing/reducing the source gas. The process is repeated, thereby depositing layers of the reaction product. The ALD may be performed using a film forming apparatus in which each gas is supplied in a state where a wafer boat holding a plurality of wafers in a form of a shelf is loaded in a vertical reaction vessel.

In manufacturing semiconductor devices, semiconductor devices may need to be produced for various uses but in a small quantity for each use. In this case, a relatively small number of wafers in the same lot are held in holding areas (slots) of the wafer boat, and the ALD is then performed. In the wafer boat, a dummy wafer is held in the slot where no wafer is provided so as to prevent the state of a film formed on the wafer from being changed due to a change in the number of wafers.

However, a large number of dummy wafers are consumed in this process. Also, in the film forming apparatus, even when a film forming process is performed only once, a time taken to load and unload the wafer boat into and from the apparatus, a time taken to load and unload wafers and dummy wafers into and from slots of the wafer boat, a time taken to vacuumize the inside of a reaction vessel before the film forming process, a time taken to heat the wafers before the film forming process, and the like are required in addition to a time required to perform the film forming process. Therefore, if the number of wafers that can be held in the wafer boat is small, the number of times the film forming processes are performed should be increased for processing an arbitrary number of wafers and hence a time (overhead time) for the increased number of times performed is additionally required in the film forming process. As a result, a problem that the productivity of the apparatus degrades is caused. It may be considered to wait until many wafers to be subjected to the same film forming process become ready to be transferred into the wafer boat. However, even in this case, since the timing for starting the process also becomes late, it is difficult to improve the productivity of the apparatus.

For example, there is known a film forming apparatus in which a partition plate surrounding a wafer boat is installed in a reaction vessel to partition the inside of the reaction vessel. In the film forming apparatus, different gases are supplied into the respective divided areas, and a source gas, a purge gas, a reaction gas, and a purge gas are repeatedly supplied to the respective areas in this order, thereby performing processes. Accordingly, ALDs are performed in the respective divided areas such that timings of the ALDs become different between the respective areas by one step. Thus, the amount of gas supplied into each area per unit time can be large. However, even if the processes are performed in the above-described manner, it is impossible to resolve the problems associated with the productivity in the apparatus or waste of dummy wafers.

### SUMMARY

Some embodiments of the present disclosure provide a technology for enhancing the productivity of a film forming apparatus in which a film is formed in a state in which a substrate holding unit holding a plurality of substrates in a form of a shelf is disposed in a vertical reaction vessel.

According to one embodiment of the present disclosure, there is provided a film forming apparatus in which a film is formed by alternately supplying a source gas and a reaction gas reacting with the source gas to generate a reaction product into a vertical reaction vessel having a substrate holding unit disposed therein, the substrate holding part holding a plurality of substrates in a form of a shelf, the film forming apparatus including: a first source gas supply part and a second source gas supply part configured to limitedly supply the source gas only to a first substrate holding area and a second substrate holding area, respectively, among the first substrate holding area and the second substrate holding area disposed along an arrangement direction in which the substrates are arranged in the substrate holding part; a reaction gas supply part configured to supply the reaction gas to the first substrate holding area and the second substrate holding area; a purge gas supply part configured to supply a purge gas for preventing the source gas supplied to one of the first substrate holding area and the second substrate holding area from being supplied to the other substrate holding area; a division-purpose substrate held between the first substrate holding area and the second substrate holding area in the substrate holding part to divide the substrate holding part into the first substrate holding area and the second substrate holding area; and a control part configured to output a control signal such that a first cycle including supplying the source gas to the first substrate holding area and supplying the reaction gas to the first substrate holding area and a second cycle including supplying the source gas to the second substrate holding area and supplying the reaction gas to the second substrate holding area are each performed plural times.

According to another embodiment of the present disclosure, there is provided a film forming apparatus in which a film is formed by alternately supplying a source gas and a reaction gas reacting with the source gas to generate a reaction product into a vertical reaction vessel having a substrate holding unit disposed therein, the substrate holding part holding a plurality of substrates in a form of a shelf, the film forming apparatus including: a first reaction gas supply part and a second reaction gas supply part configured to limitedly supply the reaction gas only to a first substrate holding area and a second substrate holding area, respectively, among the first substrate holding area and the second substrate holding area disposed along an arrangement direction in which the substrates are arranged in the substrate holding part; a source gas supply part configured to supply the source gas to the first substrate holding area and the second substrate holding area; a purge gas supply part configured to supply a purge gas for preventing the reaction gas supplied to one of the first substrate holding area and the second substrate holding area from being supplied to the other substrate holding area; a division-purpose substrate held between the first substrate holding area and the second substrate holding area in the substrate holding part to divide the substrate holding part into the first substrate holding area and the second substrate holding area; and a control part configured to output a control signal such that a first cycle including supplying the source gas to the first substrate holding area and supplying the reaction gas to the first substrate holding area and a second cycle including supplying the source gas to the second substrate holding area and supplying the reaction gas to the second substrate holding area are each performed plural times.

According to another embodiment of the present disclosure, there is provided a film forming apparatus in which a film is formed by alternately supplying a source gas and a reaction gas reacting with the source gas to generate a reaction product into a vertical reaction vessel having a substrate holding part disposed therein, the substrate holding part holding a plurality of substrates in a form of a shelf, the film forming apparatus including: a first source gas supply part configured to limitedly supply the source gas at a first flow rate only to a first substrate holding area, among the first substrate holding area and a second substrate holding area disposed along an arrangement direction in which the substrates are arrange in the substrate holding part; a second source gas supply part configured to supply the source gas at a second flow rate greater than the first flow rate only to the second substrate holding area, in parallel with the supply of the source gas from the first source gas supply part; a gas supply part for pressure adjustment configured to supply a pressure adjustment gas for adjusting a pressure distribution in the first substrate holding area and the second substrate holding area to the first substrate holding area when the source gas is supplied to the first substrate holding area and the second substrate holding area; a division-purpose substrate held between the first substrate holding area and the second substrate holding area in the substrate holding part to divide the substrate holding part into the first substrate holding area and the second substrate holding area; and a control part configured to output a control signal such that a cycle including supplying the source gas to the first substrate holding area and supplying the reaction gas to the first substrate holding area and a cycle including supplying the source gas to the second substrate holding area and supplying the reaction gas to the second substrate holding area are each performed plural times.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal sectional side view of a film forming apparatus according to an embodiment of the present disclosure.

FIG. 2 is a transverse sectional plan view of the film forming apparatus.

FIG. 3 is an explanatory view illustrating a relationship between nozzles of the film forming apparatus and wafers mounted in a wafer boat.

FIG. 4 is a configuration view of a gas supply system installed in the film forming apparatus.

FIG. 5 is a timing chart illustrating steps of a process performed by the film forming apparatus.

FIG. 6 is a view illustrating a process performed by the film forming apparatus.

FIG. 7 is a view illustrating a process performed by the film forming apparatus.

FIG. 8 is a view illustrating a process performed by the film forming apparatus.

FIG. 9 is a view illustrating a process performed by the film forming apparatus.

FIG. 10 is a schematic view illustrating another example of configuration of the film forming apparatus.

FIG. 11 is a diagram illustrating examples of processes performed by the film forming apparatus.

FIG. 12 is a diagram illustrating examples of processes performed by the film forming apparatus.

FIG. 13 is a diagram illustrating examples of processes performed by the film forming apparatus.

FIG. 14 is a diagram illustrating examples of processes performed by the film forming apparatus.

FIG. 15 is a diagram illustrating examples of processes performed by the film forming apparatus.

FIG. 16 is a schematic view illustrating another example of configuration of the film forming apparatus.

FIG. 17 is a schematic view illustrating another example of configuration of the film forming apparatus.

FIG. 18 is a graph illustrating results of evaluation tests.

FIG. 19 is a timing chart illustrating steps of another process performed by the film forming apparatus.

FIG. 20 is a timing chart illustrating steps of another process performed by the film forming apparatus.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

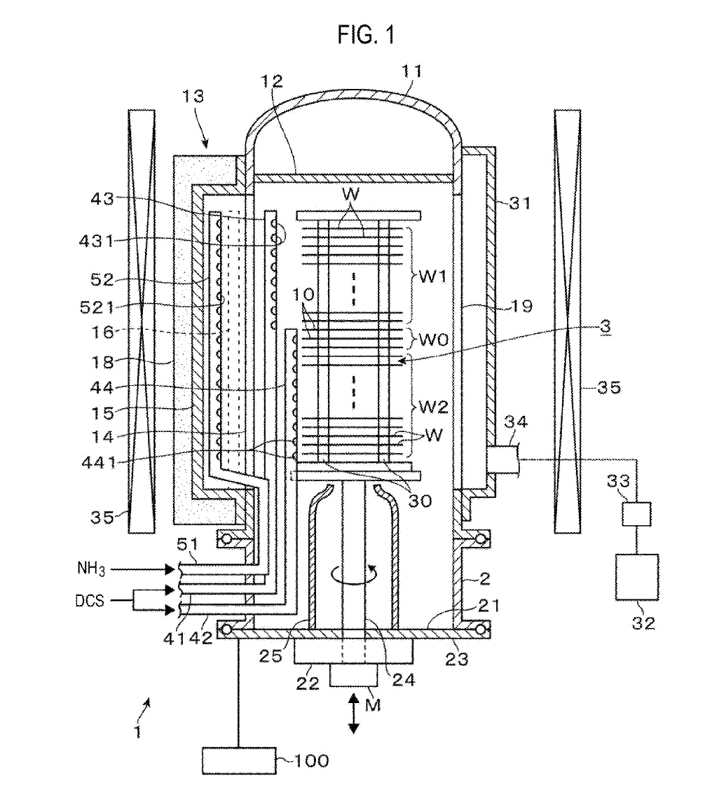

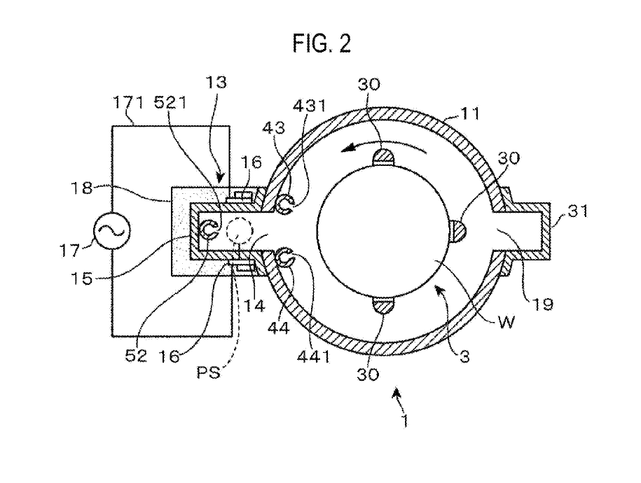

A film forming apparatus 1 according to an embodiment of the present disclosure will be described with reference to FIGS. 1 and 2. FIGS. 1 and 2 are a longitudinal sectional side view and a transverse sectional plan view of the film forming apparatus 1, respectively. Reference numeral 11 in FIGS. 1 and 2 designates a reaction vessel formed of, e.g., quartz in the shape of a vertical cylinder. An upper portion in the reaction vessel 11 is sealed by a ceiling plate 12 made of quartz. A manifold 2 formed of, e.g., a stainless steel in the shape of a cylinder, is connected to a lower end of the reaction vessel 11. A lower end of the manifold 2 is opened as a substrate loading/unloading port 21 and configured to be airtightly closed by a lid 23 made of quartz, the lid 23 being mounted to a boat elevator 22. A rotating shaft 24 is provided to penetrate a central portion of the lid 23, and a wafer boat 3 serving as a substrate holding unit is mounted on the upper end of the rotating shaft 24.

The wafer boat 3 has, for example, three posts 30, and supports outer edge portions of wafers W and dummy wafers 10 serving as substrates for division, thereby holding the wafers W and the dummy wafers 10 in a form of a shelf. The boat elevator 22 is liftable by a lifting mechanism (not shown), and the rotating shaft 24 is rotatable around a vertical axis by a motor M constituting a driving unit. Reference numeral 25 in FIGS. 1 and 2 designates a heat insulation unit. With this configuration, the wafer boat 3 is liftable between a processing position at which the wafer boat 3 is loaded (carried) into the reaction vessel 11 while the substrate loading/unloading port 21 of the reaction vessel 11 is closed by the lid 23, and an unloading position below the reaction vessel 11. The wafer boat 3 will be described in detail later.

A plasma generation unit 13 is installed at a portion of the sidewall of the reaction vessel 11. The plasma generation unit 13 is formed by airtightly joining a division wall 15 made of, e.g., quartz and having a concave cross section, to the outer wall of the reaction vessel 11 such that the division wall 15 covers a vertically elongated opening 14 formed through the sidewall of the reaction vessel 11. The opening 14 is formed in an elongated shape along the vertical direction in a range covering all the wafers W and the dummy wafers 10 held by the wafer boat 3. A pair of plasma electrodes 16 opposite to each other along the length direction (vertical direction) of the division wall 15 are installed on outer surfaces of both sidewalls of the division wall 15. A high-frequency power source 17 for plasma generation is connected to the plasma electrodes 16 through a feeding line 171, so that plasma can be generated by applying a high-frequency voltage of, e.g., 13.56 MHz to the plasma electrodes 16. An insulation protection cover 18 made of, e.g., quartz is installed on the outside of the division wall 15 to cover the division wall 15.

A vertically elongated opening 19 is formed in a portion of the circumferentially extending sidewall of the reaction vessel 11, i.e., an area opposite to the plasma generation unit 13 in this example, so as to vacuum-exhaust the atmosphere in the reaction vessel 11. The opening 19 is formed along an arrangement direction in which the wafers W and the dummy wafers 10 are arranged while facing the area in which the wafers W and the dummy wafers 10 are arranged in the wafer boat 3.

An exhaust cover member 31 made of, e.g., quartz in the shape of a U-shaped cross section, is installed to the opening 19 to cover the opening 19. The exhaust cover member 31 is configured, for example, to vertically extend along the sidewall of the reaction vessel 11. For example, an exhaust pipe 34 having a vacuum pump 32 and a pressure adjustment valve 33, which constitute a vacuum exhaust unit, is connected to a lower portion of the exhaust cover member 31.

A first source gas supply path 41 and a second source gas supply path 42 for supplying a silane-based gas serving as a source gas, for example, dichlorosilane (DCS: SiH₂Cl₂), are inserted into the sidewall of the manifold 2. A first source gas nozzle 43 (hereinafter, referred to as a “first nozzle”) and a second source gas nozzle 44 (hereinafter, referred to as a “second nozzle”) are installed at the leading portions of the first source gas supply path 41 and the second source gas supply path 42, respectively. Each of the first nozzle 43 serving as a first source gas supply unit and the second nozzle 44 serving as a second source gas supply unit is made of, for example, a quartz tube having a circular cross section and, as shown in FIG. 1, is vertically provided at a radially outer side of the wafer boat 3 in the reaction vessel 11 to extend along the arrangement direction of the wafers W held by the wafer boat 3. For example, as shown in FIG. 2, the first nozzle 43 and the second nozzle 44 are disposed with the opening 14 of the plasma generation unit 13 interposed therebetween. Also, in FIG. 1, for convenience of illustration, both of the first and second nozzles 43 and 44 are shown side by side when viewed from the side.

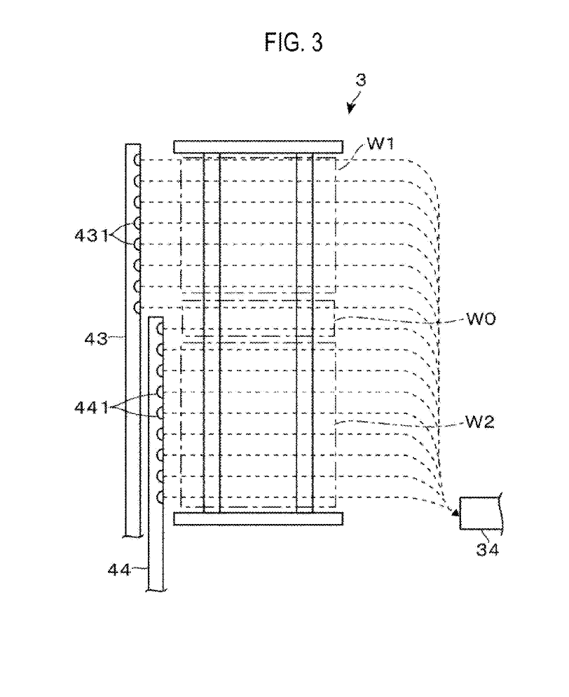

Next, the first nozzle 43 and the second nozzle 44 will be described in detail with reference to FIG. 3. A plurality of, for example, sixty gas ejection holes for ejecting a source gas are formed in each of the first nozzle 43 and the second nozzle 44 with predetermined intervals along the length direction of the nozzles 43 and 44. The gas ejection holes of the first nozzle 43 are designated by reference numeral 431, and the gas ejection holes of the second nozzle 44 are designated by reference numeral 441. The gas ejection holes 431 are positioned above the gas ejection holes 441. A purge gas is also ejected from the gas ejection holes 431 and 441, so that the first nozzle 43 and the second nozzle 44 also constitute a purge gas supply unit.

On the other hand, a plurality of slots (holding areas) are vertically provided with equal intervals in the wafer boat 3, and the wafers W and the dummy wafers 10 are horizontally held in the respective slots. A plurality of wafers W are held in upper and lower portions of the wafer boat 3, respectively, while, for example, a plurality of dummy wafers 10 are held between the group of the wafers W in the upper portion and the group of the wafers W in the lower portion to divide the groups of the wafers. In this embodiment, the area in which the group of the wafers W in the upper portion is held is represented as a holding area W1 in the wafer boat 3, the area in which the group of the wafers W in the lower portion is held is represented as a holding area W2 in the wafer boat 3, and the area in which the dummy wafers 10 are held is represented as a holding area WO. The film forming apparatus 1 is configured such that silicon nitride (SiN) films having different film thicknesses can be formed by individually performing ALD on the wafers W of the holding area W1 and the wafers W of the holding area W2, respectively, in the same reaction vessel 11.

In FIG. 3, the gas flow in the reaction vessel is schematically shown by dotted line arrows. The gas ejection holes 431 of the first nozzle 43 are horizontally opened to face only the holding area W1, among the holding areas W1 and W2, to limitedly eject the source gas only to the holding area W1. The gas ejection holes 441 of the second nozzle 44 are horizontally opened to face only the holding area W2, among the holding areas W1 and W2, to limitedly eject the source gas only to the holding area W2. In the wafer boat 3, when wafers W are mounted at a plurality of slots existing in or near a boundary between the area in which the gas is supplied through the gas ejection holes 431 and the area in which the gas is supplied through the gas ejection holes 441, it is difficult to control the thickness of the film formed on the wafers W due to diffusion of the gas supplied through the gas ejection holes 431 and 441. Hence, the dummy wafers 10 are mounted as described above, thereby preventing a waste of the wafers W. Accordingly, it is possible to reduce the cost required in processing.

Referring back to FIGS. 1 and 2, a reaction gas supply path 51 for supplying ammonia (NH₃) gas serving as a reaction gas is inserted into the sidewall of the manifold 2, and a reaction gas nozzle 52 made of, e.g., a quartz tube, and constituting a reaction gas supply unit is installed at the leading end portion of the reaction gas supply path 51. The reaction gas is a gas that generates a reaction product by reaction with molecules of the source gas. The reaction gas nozzle 52 extends upward in the reaction vessel 11 and is bent in the middle of the reaction vessel 11 so as to be disposed in the plasma generation unit 13. In the plasma generation unit 13, the reaction gas nozzle 52 is provided with gas ejection holes 521 opened with intervals along the length direction of the nozzle 52. The gas ejection holes 521 are horizontally opened such that the reaction gas can be supplied to each wafer W of the holding areas W1 and W2.

As shown in FIG. 1, a cylindrical heater 35 serving as a heating unit is installed to surround the outer circumference of the reaction vessel 11. Practically, the heater 35 is divided along the arrangement direction of the wafers W, and temperature can be individually controlled for each divided area. However, in this embodiment, the heater 35 is illustrated like a single body in the arrangement direction of the wafers W and controls the divided areas to the same temperature.

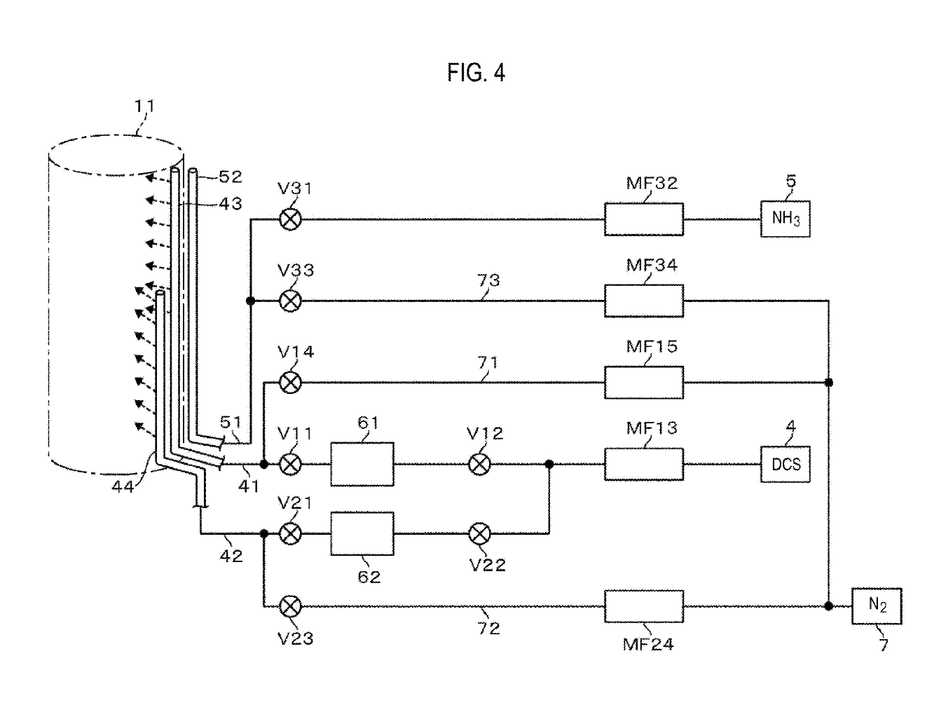

Next, a gas supply system installed in the film forming apparatus 1 will be described with reference to FIG. 4. One end of the first source gas supply path 41 is connected to a supply source 4 of dichlorosilane (DCS) serving as a source gas, and the first source gas supply path 41 has a valve V11, a first tank 61, a valve V12, and a flow rate adjustment unit MF13, which are provided in this order from the reaction vessel 11. The first source gas supply path 41 branches at a downstream side of the valve V11 and is connected to a supply source 7 of nitrogen (N₂) gas serving as a purge gas through a first purge gas supply path 71 having a valve V14 and a flow rate adjustment unit MF15, which are provided in this order toward an upstream side. The valve operates to supply the gas and stop the supply thereof, and the flow rate adjustment unit operates to adjust the supply amount of the gas. The later-described valves and flow rate adjustment units also have the same functions.

Similarly, the second source gas supply path 42 has one end connected to the first source gas supply path 41 between the valve V12 and the flow rate adjustment unit MF13 and is provided with a valve V21, a second tank 62, and a valve V22 in this order from the reaction vessel 11. Also, the second source gas supply path 42 branches at a downstream side of the valve V21 and is connected to the supply source 7 of the N₂ gas through a second purge gas supply path 72 having a valve V23 and a flow rate adjustment unit MF24, which are provided in this order toward an upstream side.

The first tank 61 and the second tank 62 are configured such that when DCS gases are continuously introduced into the first tank 61 and the second tank 62, respectively, by closing the valves V11 and V21 at their downstream sides and opening the valves V12 and V22 at their upstream sides, the DCS gasses are stored in the first tank 61 and the second tank 62 to increase the pressures of the tanks 61 and 62. After the pressures of the first tank 61 and the second tank 62 are increased, the valves V11 and V21 at the downstream sides are opened in a state in which the valves V12 and V22 at the upstream sides are closed, thereby supplying the DCS gases in the first tank 61 and the second tank 62 into the reaction vessel 11 at a relatively high flow rate, e.g., about 300 cc/min

The reaction gas supply path 51 has one end connected to a supply source 5 of NH₃ gas and is provided with a valve V31 and a flow rate adjustment unit MF32 in this order from the reaction vessel 11. The reaction gas supply path 51 branches at a downstream of the valve V31 and is connected to the supply source of nitrogen gas through a purge gas supply path 73 having a valve V33 and a flow rate adjustment unit MF34, which are provided in this order toward an upstream side.

The film forming apparatus 1 includes a control unit 100, as shown in FIG. 1. The control unit 100 includes a computer, and a memory unit provided in the computer stores therein a program including a group of control steps (instructions) for the operation of the film forming apparatus 1, i.e., the film forming process being performed on wafers Win the reaction vessel 11. The program is stored in, for example, a storage medium such as a hard disc, a flexible disc, a compact disc, a magneto-optical disc, or a memory card, and installed on the computer from the storage medium.

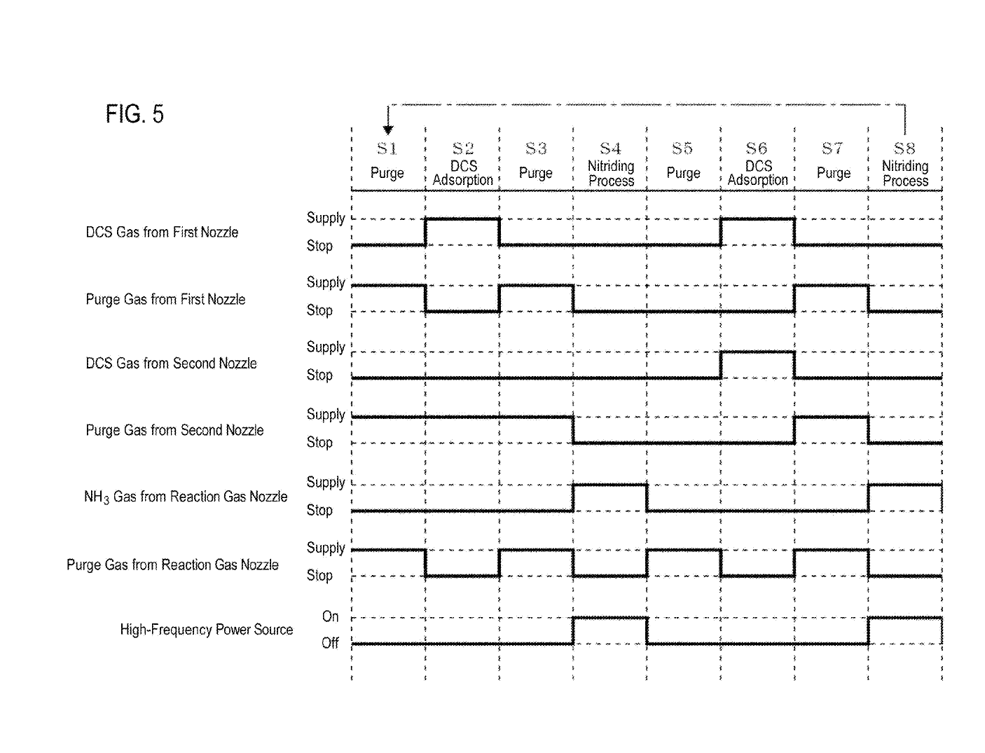

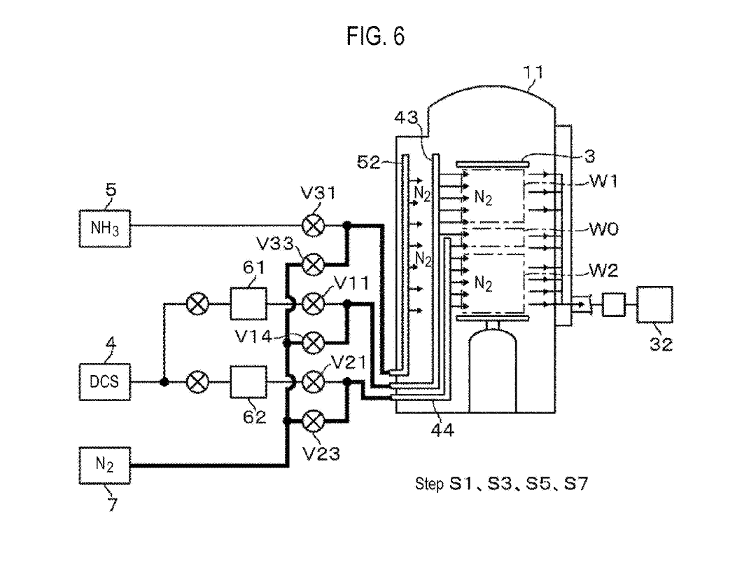

The timing chart of FIG. 5 illustrates a state of supplying various kinds of gases into the reaction vessel 11 from the nozzles, a state of stopping the supply, and a state of turning on/off the high-frequency power source 17, for each step of the process of the film forming apparatus 1. The operation of the film forming apparatus 1 will be described with reference to this chart and FIGS. 6 to 9 illustrating the flow of each gas in the gas supply system and the reaction vessel 11 in each step. In FIGS. 6 to 9, flow paths through which the gas flows are shown by a bold line as compared with flow paths through which the gas does not flow. However, in the chart of FIG. 5 and FIGS. 6 to 9, even in a step to which an indication that No N₂ gas is supplied from the nozzles 43, 44, and 52 is given, the N₂ gas is actually supplied at a relatively low flow rate so as to prevent an atmosphere of the reaction vessel 11 from entering into the nozzles or so as to dilute a reaction gas and a source gas to an appropriate concentration. For this reason, although the valve for supplying/stopping the N₂ gas is described as closed in the following description, the valve is not completely closed but actually slightly opened to allow the N₂ gas to flow.

As shown in FIG. 3, after unprocessed wafers W and dummy wafers 10 are mounted in the wafer boat 3, the wafer boat 3 is then carried (loaded) into the reaction vessel 11, and the inside of the reaction vessel 11 is set to a vacuum atmosphere of about 13.33 Pa (0.1 Ton) by the vacuum pump 32. Each wafer W in the holding areas W1 and W2 is heated to a predetermined temperature, e.g., 500 degrees C. by the heater 35, and the wafer boat 3 is rotated. The first and second tanks 61 and 62 are filled with DCS gas until the pressures within the tanks reach a preset pressure, e.g., 33.33 kPa (250 Ton) to 53.33 kPa (400 Torr).

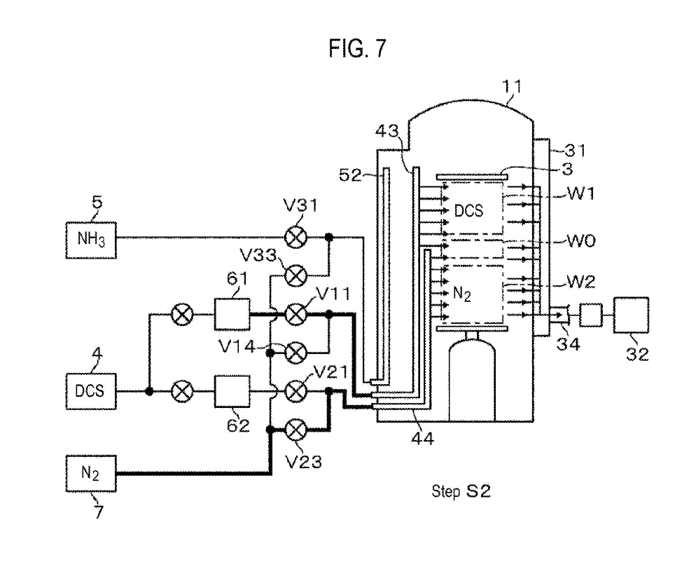

In this state, the valves V14, V23, and V33 are opened, and N₂ gas is supplied as a purge gas into the reaction vessel 11 through the first nozzle 43, the second nozzle 44, and the reaction gas nozzle 52, thereby purging the inside of the reaction vessel 11 (FIG. 6 and Step S1). Next, the valves V14 and V33 are closed, and the valve V11 is opened in a state in which the valve V23 is opened, i.e., a state in which the purge gas is limitedly supplied only to the holding area W2 of the wafers W from the second nozzle 44, thereby supplying the DCS gas in the first tank 61 toward the holding area W1 of the wafers from the first nozzle 43 (FIG. 7 and Step S2).

The DCS gas is limitedly supplied only to the holding area W1 while the supply thereof into the holding area W2 is prevented, due to various points, e.g., a point that the gas ejection holes 431 of the first nozzle 43 are limitedly opened only to the holding area W1 among the two holding areas W1 and W2, i.e., the gas ejection holes 431 is not opened to the holding area W2, a point that the purge gas is supplied to the holding area W2, and a point that the holding areas W1 and W2 are spaced apart from each other since the holding area W0 of the dummy wafers 10 is disposed between the holding areas W1 and W2. The DCS gas supplied to the holding area W1 flows from one side of a surface of each wafer W in the holding area W1 to the other side thereof, so that molecules of the DCS gas are adsorbed onto the surface of the wafer W. Remaining surplus DCS gas flows downward in the exhaust cover member 31 at the other side of the wafer W due to the exhaust through the exhaust pipe 34 and is removed through the exhaust pipe 34 together with the purge gas supplied to the holding area W2 and introduced into the exhaust cover member 31.

Thereafter, the valve V11 is closed to stop the supply of the DCS gas from the first nozzle 43. Then the valves V 14 and V33 are opened to supply the purge gas into the reaction vessel 11 from the first nozzle 43, the second nozzle 44, and the reaction gas nozzle 52, in the same manner as Step S1 shown in FIG. 6, so that the DCS gas in the reaction vessel 11 is purged (Step S3). Thereafter, the valves V14 and V33 are closed, and simultaneously, the valve V31 is opened, so that NH₃ gas as a reaction gas is supplied into the reaction vessel 11. Together with the supply of the NH₃ gas, the high-frequency power source 17 is turned on. Thus, the NH₃ gas is converted into plasma, and active species of the NH₃ gas are generated.

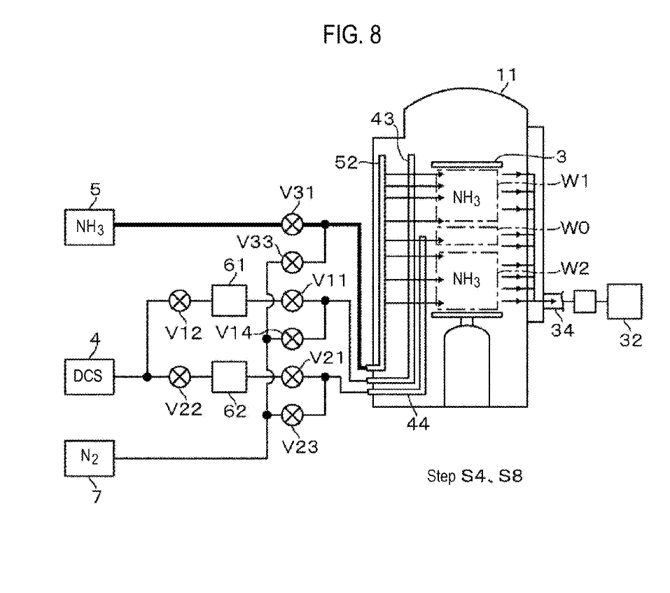

The active species are supplied to the holding areas W1 and W2. Thus, in each wafer W of the holding area W1, the molecules of the DCS gas adsorbed onto the surface of the wafer W react with the active species, and silicon atoms in the DCS gas are nitrided, thereby generating a molecular layer of silicon nitride (SiN) (FIG. 8 and Step S4). Since the molecules of the DCS gas are not adsorbed onto the surface of the wafer W of the holding area W2, the active species supplied to the holding area W2 do not react with the surface of the wafer W but pass through the surface of the wafer W. Remaining surplus active species of NH₃ supplied to the holding area W1 and active species of NH₃ supplied to the holding area W2 are introduced into the exhaust cover member 31, and all of them are exhausted through the exhaust pipe 34. While the active species of the NH₃ gas are supplied into the reaction vessel 11 as described above, the valve V12 is opened and the DCS gas is again supplied to the first tank 61. If the pressure of the first tank 61 reaches a preset pressure, the valve V12 is closed. In FIG. 8, the flow of the DCS gas in the first tank 61 is not indicated.

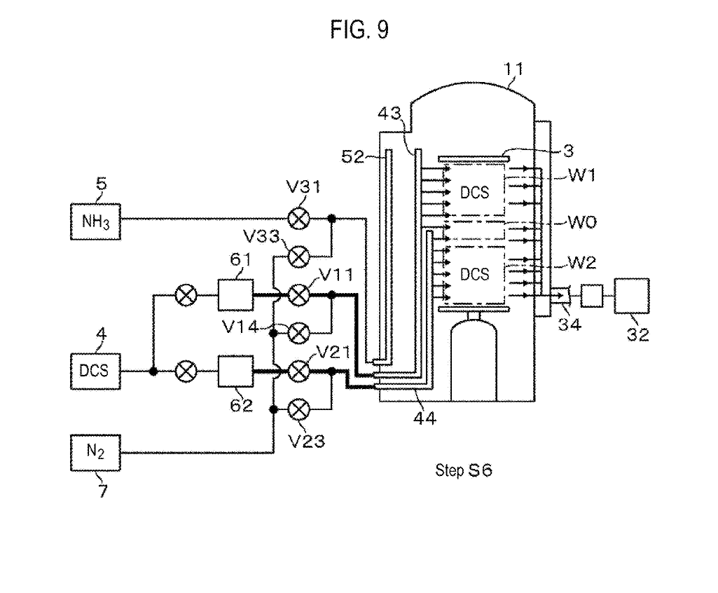

Thereafter, the valve V31 is closed, so that the supply of the NH₃ gas into the reaction vessel 11 is stopped, and simultaneously, the high-frequency power source 17 is turned off to stop the generation of plasma. Then, the valves V14, V23, and V33 are opened, and the purge gas is supplied into the reaction vessel 11 from the first nozzle 43, the second nozzle 44, and the reaction gas nozzle 52, in the same manner as Steps 51 and S3 shown in FIG. 6, thereby purging the NH₃ gas and its active species remaining in the reaction vessel 11 (Step S5). Thereafter, the valves V14, V23, and V33 are closed, and simultaneously, the valves V11 and V21 are opened. Then, the DCS gases in the first tank 61 and the second tank 62 are supplied to the holding areas W1 and W2 through the first nozzle 43 and the second nozzle 44, respectively (FIG. 9 and Step S6). Accordingly, the molecules of the DCS gas are absorbed onto the surface of the wafer W of the holding area W2. Simultaneously, in the wafer W of the holding area W1, the molecules of the DCS gas are absorbed onto the surface of the molecular layer of SiN formed in Step S4 on the wafer W.

Thereafter, the supply of the DCS gas is stopped by closing the valves V11 and V21, and the purge gas is supplied into the reaction vessel 11 through the first nozzle 43, the second nozzle 44, and the reaction gas nozzle 52 by opening the valves V14, V23 and V33, in the same manner as Steps S1, S3, and S5, so that the DCS gas remaining in the reaction vessel 11 is purged (Step S7). Then, the valves V11, V21, and V33 are closed, and simultaneously, the valve V31 is opened. Thus, in the same manner as Step S4 shown in FIG. 8, the NH₃ gas is supplied into the reaction vessel 11, and simultaneously, the high-frequency power source 17 is turned on. Accordingly, the NH₃ gas is converted into plasma to generate active species, and the active species are supplied to the holding area W1 and the holding area W2, to react with the molecules of the DCS gas adsorbed onto the surface of each wafer W of the holding areas W1 and W2. In the wafer W of the holding area W2, a molecular layer of SiN is formed. In the wafer W of the holding area W1, a molecular layer of SiN is additionally formed on the molecular layer of SiN formed in Step S4 (Step S8).

Thereafter, the high-frequency power source 17 is turned off, and simultaneously, the valve V31 is closed, so that the supply of the NH₃ gas is stopped. Then, Steps S1 to S8 described above are repeatedly performed. Whenever a set of Steps S1 to S8 is performed once, two molecular layers of SiN are laminated in the holding area W1, and one molecular layer of SiN is laminated in the holding area W2. Since the numbers of molecular layers laminated in the holding areas W1 and W2 are different from each other after a single set of Steps S1 to S8, SiN films having different film thicknesses are formed in the holding area W1 and the holding area W2, respectively. After Steps S1 to S8 are performed a predetermined number of times, the pressure of the reaction vessel 11 is returned to an atmospheric pressure by supplying the nitrogen gas into the reaction vessel 11 from the first nozzle 43, the second nozzle 44, and the reaction gas nozzle 52, in the same manner as Step S1 described above. Then, the wafer boat 3 is carried out (unloaded), and the wafers 10 and the dummy wafers 10 are carried out from the slots of the wafer boat 3.

According to the film forming apparatus 1, the holding area W0 of the dummy wafers 10 is formed between the holding areas W1 and W2 of the wafers W in the wafer boat 3. In addition, the step in which the purge gas is supplied to the holding area W2 from the second nozzle 44 while the DCS gas is limitedly supplied only to the holding area W1 from the first nozzle 43, thereby preventing the DCS gas from being supplied to the holding area W2, and the step of supplying the DCS gas to both the holding areas W1 and W2 are performed. Accordingly, molecular layers of SiN, which are different in the laminated number, are laminated in the holding areas W1 and W2, thereby enabling to form SiN films having different film thicknesses. Thus, it is possible to improve the production efficiency of the film forming apparatus 1 and to decrease the number of dummy wafers 10 while reducing the cost required in the film forming process, by preventing the overhead time described in the BACKGROUND section from being repeatedly required, compared with the case where the wafers W are held and processed in only one holding area W1 or W2 in the wafer boat 3. In this embodiment and embodiments described later, the number of dummy wafers 10 of the holding area W0 is not limited to plural numbers and may be one.

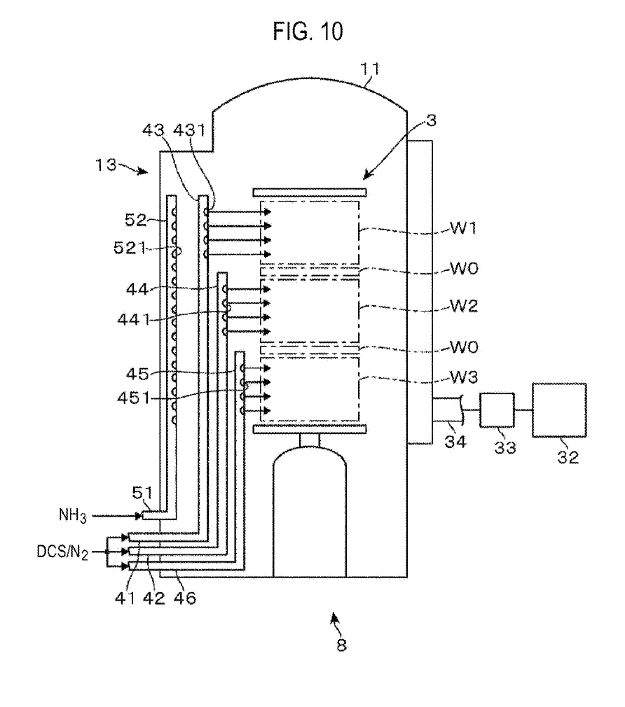

Then, a film forming apparatus 8 as a modification of the film forming apparatus 1 will be described with reference to FIG. 10, while focusing on differences between the film forming apparatuses land 8. In a wafer boat 3 loaded into the film forming apparatus 8, holding areas W1, W2, and W3 of wafers W are defined in this order from the top toward the bottom, and a plurality of wafers W are held in each of the holding areas W1 to W3. Also, holding areas W0 of dummy wafers 10 are formed between the holding areas W1 and W2 and between the holding areas W2 and W3, respectively. In addition to the first nozzle 43 and the second nozzle 44, a third nozzle 45 for supplying a DCS gas serving as a source gas into the reaction vessel 11 is installed. Reference numeral 451 in FIG. 10 designates ejection holes of the third nozzle 45, and reference numeral 46 in FIG. 10 designates a gas flow path connected to an upstream side of the third nozzle 45. The gas supply system is configured to be able to individually supply the DCS gas to the first to third nozzles 43 to 45, respectively. In the same manner as the embodiment described above, the first nozzle 43 and the second nozzle 44 limitedly supply the source gas only to the holding areas W1 and W2, respectively. In the third nozzle 45, the ejection holes 451 are opened such that they limitedly supply the DCS gas only to the holding area W3 among the holding areas W1 to W3.

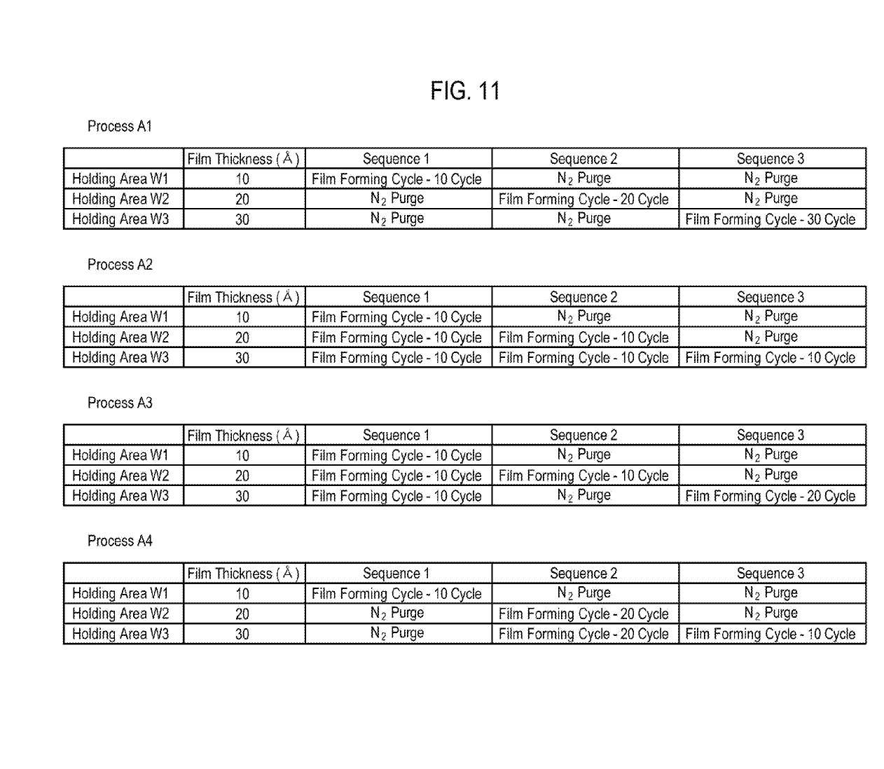

In each diagram in FIGS. 11 to 15, listed are process examples performed by the film forming apparatus 8. In each diagram, sequences indicate orders in which processes are performed, and sequences 1, 2, 3, . . . are performed in this order. In the diagram, processes performed in the respective sequence are illustrated by holding areas, and, in the same sequence, processes in respective holding areas are performed in parallel to each other. Further, in the diagram, the number of times film forming cycles are repeated is indicated with respect to the holding area in which the film forming cycle including the supply of the DCS gas and the supply of the NH₃ gas is performed in a certain sequence. More specifically, the film forming cycle refers to a series of processes corresponding to Steps S2 to S5 of the film forming apparatus 1, which are performed in the order of the supply of the DCS gas, the supply of the purge gas, the supply of the NH₃ gas converted into plasma, and the supply of the purge gas. The film forming apparatus 8 is configured to form a molecular layer of SiN having a thickness of, for example, 1 angstrom (Å), through one film forming cycle.

The supply of the DCS gas in the film forming cycle is limitedly performed only to a specified holding area, as described above. While the supply of the DCS gas is performed in a certain holding area, the purge gas is limitedly supplied only to a holding area in which the film forming cycle is not performed, so that the supply of the DCS gas to other holding areas is prevented. The holding area to which the purge gas is supplied as described above is indicated by “N₂ purge” in the diagram and may be simply described as “a holding area in which the N₂ purge is performed” in the following description. While the purge gas and reaction gas are supplied to the holding area in which the film forming cycle is performed, the purge gas and the reaction gas are also respectively supplied to other holding areas, in the same manner as the film forming apparatus 1.

The diagram indicated by “Process A1” in FIG. 11 will be described. In Process A1, SiN films having film thicknesses of, e.g., 10 angstroms (1 nm), 20 angstroms (2 nm), and 30 angstroms (3 nm) are formed on the wafers Win the holding areas W1, W2, and W3, respectively. In Sequence 1, the film forming cycle is repeatedly performed in the holding area W1 ten times, and the N₂ purge is performed on the holding areas W2 and W3 while the source gas is supplied to the holding area W1 as described above. In Sequence 2, the film forming cycle is repeatedly performed in the holding area W2 twenty times, and the N₂ purge is performed in the holding areas W1 and W3. In Sequence 3, the film forming cycle is repeatedly performed in the holding area W3 thirty times, and the N₂ purge is performed in the holding areas W1 and W2. That is, in Process A1, the operation of the film forming apparatus 8 is controlled such that a step of repeatedly performing the film forming cycle is performed in one holding area a predetermined number of times and then another holding area is subjected to the step of repeatedly performing the film forming cycle a predetermined number of times.

Then, Process A2 of FIG. 11 will be described, focusing on differences between the Process A1 and the Process A2. The film forming cycle is repeatedly performed in the holding areas W1 to W3 ten times in Sequence 1. The film forming cycle is performed only in the holding areas W2 and W3 ten times in Sequence 2, and the film forming cycle is performed only in the holding area W3 ten times in Sequence 3. That is, although the supply of the DCS gas is performed at different timings in the holding areas in Process A1, a period for which the supply of the DCS gas is simultaneously performed in all holding areas is given in Process A2. More specifically, in Process A2, the operation of the film forming apparatus 8 is controlled such that the film forming cycles are simultaneously performed in one holding area and another holding area for a predetermined repetition number N1 in one step and, in the next steps, the film forming cycles are performed only in the another holding area only the number of times (N−N1) which is obtained by subtracting the predetermined repetition number N1 from a predetermined repetition number N for which the film forming cycles should be performed in the another holding area.

Next, Process A3 of FIG. 11 will be described. The process is performed in the same manner as Process A2 with respect to Sequence 1. The film forming cycle is performed only in the holding area W2 ten times in Sequence 2, and the film forming cycle is performed only in the holding area W3 twenty times in Sequence 3. In Process A4 of FIG. 11, the film forming cycle is repeatedly performed only in the holding area W1 ten times in Sequence 1, the film forming cycle is performed only in the holding areas W2 and W3 twenty times in Sequence 2, and the film forming cycle is performed only in the holding area W3 ten times in Sequence 3.

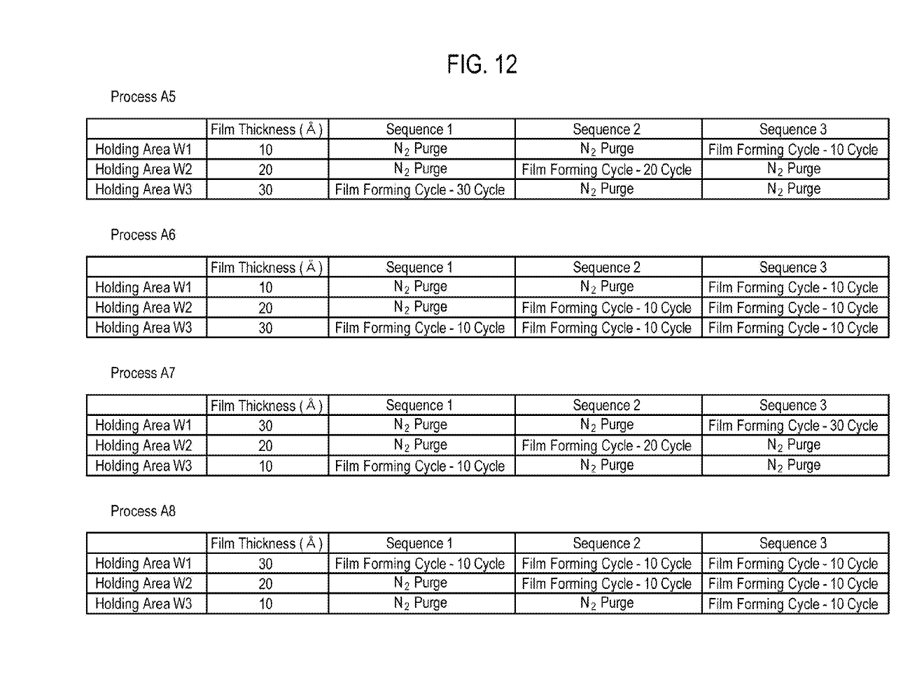

On the other hand, the film forming cycle may be started from an arbitrary holding area. In Process A5 of FIG. 12, the processes are performed in the respective holding areas in reverse order to the sequences of Process A1. That is, the film forming cycle is repeatedly performed in the holding area W3 thirty times in Sequence 1, the film forming cycle is repeatedly performed in the holding area W2 twenty times in Sequence 2, and the film forming cycle is repeatedly performed in the holding area W1 ten times in Sequence 3. Similarly, in Process A6 of FIG. 12, the processes are performed on the respective holding areas in reverse order to the sequences of Process A2.

On the other hand, the holding area in which a film having large thickness is formed may be set to an upper portion or a lower portion of the wafer boat 3. Unlike Processes A1 to A6, in Processes A7 and A8 of FIG. 12, SiN films having film thicknesses of, e.g., 30 nm, 20 nm, and 10 nm are formed on the wafers W of the holding areas W1, W2, and W3, respectively. In Process A7, the film forming cycle is performed in the holding area W3 ten times in Sequence 1, the film forming cycle is performed in the holding area W2 twenty times in Sequence 2, and the film forming cycle is performed in the holding area W1 thirty times in Sequence 3. In Process A8, the film forming cycle is performed in the holding area W1 ten times in Sequence 1, the film forming cycle is performed in the holding areas W1 and W2 ten times in Sequence 2, and the film forming cycle is performed in the holding areas W1 to W3 ten times in Sequence 3.

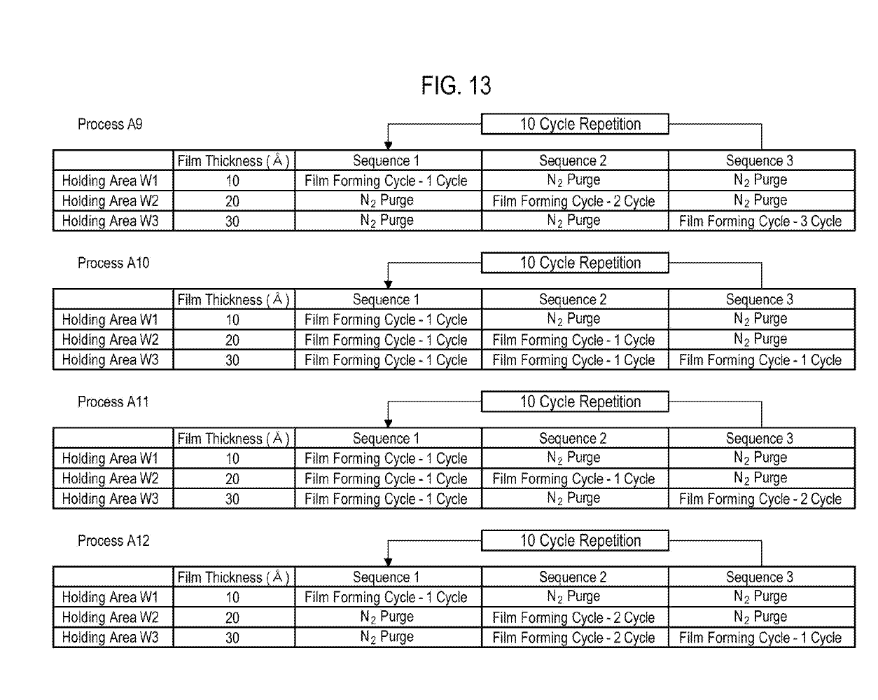

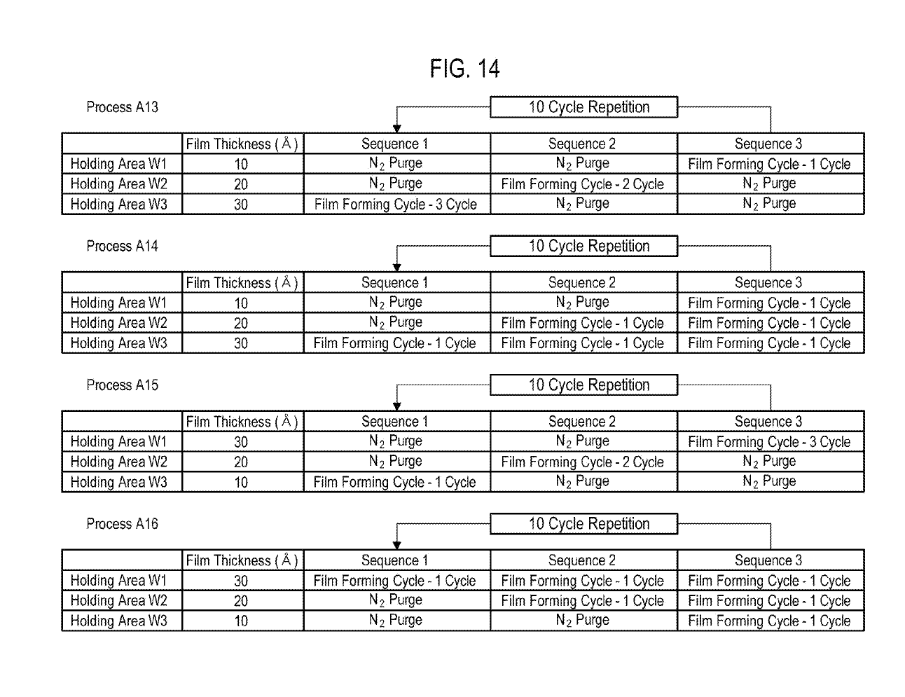

In the same manner as Processes A1 to A6, in Processes A9 to A14 shown in FIGS. 13 and 14, SiN films having film thicknesses of, e.g., 10 nm, 20 nm, and 30 nm are formed on the wafers W of the holding areas W1, W2, and W3, respectively. Unlike the processes described above, Sequences 1 to 3 are repeatedly performed in Process A9. That is, after completion of Sequence 3, Sequences 1 to 3 are performed again. The film forming cycle is performed in the holding area W1 once in Sequence 1, the film forming cycle is performed in the holding area W2 twice in Sequence 2, and the film forming cycle is performed in the holding area W3 three times in Sequence 3. Then, a cycle of Sequences 1 to 3 is repeatedly performed ten times. That is, the film forming cycles are performed in the respective holding areas W1, W2, and W3 totally ten times, twenty times, and thirty times, respectively. That is, in Process A9, a cycle set including a film forming cycle set to be performed in one holding area and a film forming cycle set to be performed in another holding area after the film forming cycle performed in the one holding area is set to be repeatedly performed plural times.

Next, Process A10 will be described. The film forming cycle is performed in the holding areas W1 to W3 once in Sequence 1, the film forming cycle is performed only in the holding areas W2 and W3 once in Sequence 2, and the film forming cycle is performed only in the holding area W3 once in Sequence 3. Then, a cycle of Sequences 1 to 3 is repeatedly performed ten times. As described above, in Process A10, a cycle set including i) a film forming cycle set to be performed in one holding area and another holding area and ii) a film forming cycle set to be performed only in the another holding area without performing in the one holding area after the film forming cycle of i) is set to be performed plural times.

Then, Process A11 will be described. The film forming cycle is performed in the holding areas W1 to W3 once in Sequence 1, the film forming cycle is performed in the holding area W2 once in Sequence 2, and the film forming cycle is performed in the holding area W3 twice in Sequence 3. Then, a cycle of Sequences 1 to 3 is repeatedly performed ten times. Also, Process A12 will be described. The film forming cycle is performed in the holding area W1 once in Sequence 1, the film forming cycle is performed in the holding areas W2 and W3 twice in Sequence 2, and the film forming cycle is performed in the holding area W3 once in Sequence 3. Then, a cycle of Sequences 1 to 3 is repeatedly performed ten times.

In Processes A9 to A12, when a cycle set of Sequences 1 to 3 is repeated ten times, the holding areas W1, W2 and W3 are subjected to the film forming cycles a total of ten times, twenty times and thirty times, respectively. The number of times the film forming cycle is performed in the holding area W1, the number of times the film forming cycle is performed in the holding area W2 and the number of times the film forming cycle is performed in the holding area W3 in each cycle set can be determined by dividing the total numbers of times of the film forming cycles in the holding areas W1 to W3, i.e., ten times, twenty times and thirty times, by ten which means the number of times the cycle set of Sequences 1 to 3 is repeated, respectively.

In Process A13 of FIG. 14, the process is performed in reverse order to Sequences 1 to 3 of Process A9. In Process A14 of FIG. 14, the process is performed in reverse order to Sequences 1 to 3 of Process A10. In the same manner as Processes A7 and A8, in Processes A15 and A16 of FIG. 14, SiN films of 30 nm, 20 nm, and 10 nm are formed on the wafers W of the holding areas Wl, W2, and W3, respectively. Process A15 is a process similar to Process A13, except that the film forming cycle is performed in the holding area W3 once in Sequence 1, and the film forming cycle is performed in the holding area W1 three times in Sequence 3. In Process A16, the film forming cycle is performed in the holding area W1 once in Sequence 1, the film forming cycle is performed in the holding areas W1 and W2 once in Sequence 2, and the film forming cycle is performed in the holding areas W1 to W3 once in Sequence 3. Then, a cycle of Sequences 1 to 3 is repeatedly performed ten times.

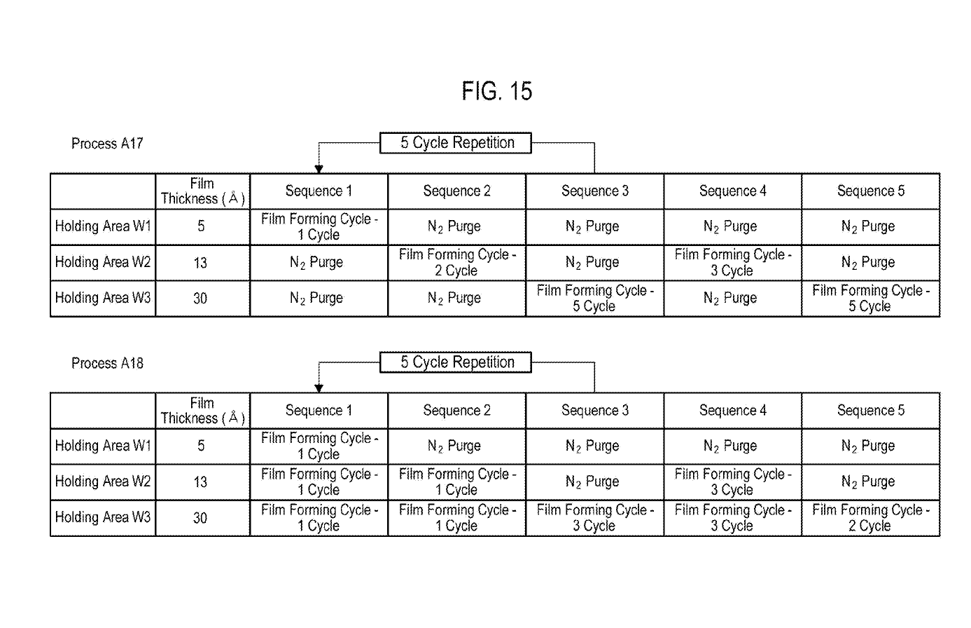

In Processes A17 and A18 of FIG. 15, SiN films having film thicknesses of, e.g., 5 nm, 13 nm, and 30 nm are formed on the wafers W of the holding areas W1, W2, and W3, respectively. In Processes A17 and A18, Sequences 1 to 5 are defined, wherein a cycle of Sequences 1 to 3 is repeatedly performed five times and then Sequences 4 and 5 are sequentially performed. In Process A17, the film forming cycle is performed in the holding area W1 once in Sequence 1, the film forming cycle is performed in the holding area W2 twice in Sequence 2, the film forming cycle is performed in the holding area W3 five times in Sequence 3, the film forming cycle is performed in the holding area W2 three times in Sequence 4, and the film forming cycle is performed in the holding area W3 five times in Sequence 5.

In Process A18, the film forming cycle is performed in the holding areas W1 to W3 once in Sequence 1, the film forming cycle is performed in the holding areas W2 and W3 once in Sequence 2, the film forming cycle is performed in the holding area W3 three times in Sequence 3. The film forming cycle is performed in the holding areas W2 and W3 three times in Sequence 4, and the film forming cycle is performed in the holding area W3 twice in Sequence 5. As described above, by appropriately setting the number of times the cycles repeating the sequences are performed and the number of times the film forming cycles are performed in one sequence, it is possible to appropriately adjust the thickness of a film formed on the wafer W of each holding area.

When each of the above-described processes or each of the later-described processes is performed, the output of the heater 35 may be controlled such that the wafers W in the holding areas W1 to W3 have the same temperature. Alternatively, the output of the heater 35 may be controlled such that the wafers W in the holding areas W1 to W3 are different in temperature. The output of the heater 35 may be controlled such that the holding area W0 for the dummy wafers 10 has the same temperature as the holding areas W1 to W3 or such that the holding areas W1 to W3 are different from the holding area W0 in temperature. In this manner, it is possible to independently control the temperature of each holding area of the wafers 10 and the dummy wafers 10.

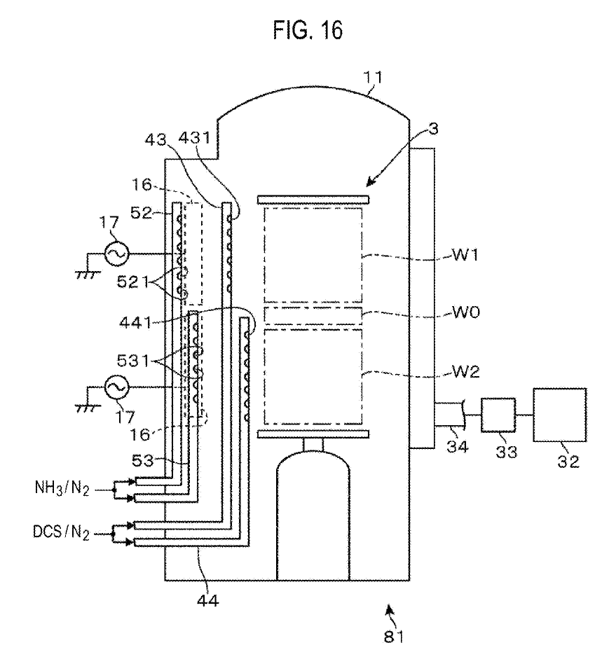

Next, a film forming apparatus 81 shown in FIG. 16 will be described focusing on differences between the film forming apparatuses 1 and 81. The film forming apparatus 81 is configured such that NH₃ gas can be individually supplied to the holding areas W1 and W2. Specifically, the reaction gas nozzle 52 and a reaction gas nozzle 53 are installed, and ejection holes 521 and 531 are formed in the reaction gas nozzles 52 and 53 to limitedly supply gases only to holding areas W1 and W2, respectively. Although the illustration of the gas supply system is omitted, the gas supply system is configured such that NH₃ gas and N2 gas are individually supplied to the reaction gas nozzle 52 and 53, respectively. The gas supply system is configured such that the concentration of the NH₃ gas supplied from the reaction gas nozzle 52 is higher than that of the NH₃ gas supplied from the reaction gas nozzle 53. The electrodes 16 for generating plasma are vertically divided into two electrode pairs, so that the high-frequency power source 17 is connected to the respective electrodes 16. Accordingly, the NH₃ gases supplied from the reaction gas nozzles 52 and 53 can be individually converted into plasma.

In the film forming apparatus 81, DCS gases are supplied to the holding areas W1 and W2, for example, from the first nozzle 43 and the second nozzle 44 in parallel. Thereafter, NH₃ gas is supplied from the reaction gas nozzle 52 and converted into plasma by the upper electrodes 16, so that active species are limitedly supplied only to the holding area W1. Accordingly, a molecular layer of SiN is formed on a surface of the wafer W of the holding area W1. During the supply of the NH₃ gas from the reaction gas nozzle 52, a purge gas is limitedly supplied only to the holding area W2 from the reaction gas nozzle 53, so that it is possible to prevent the active species from reacting with DCS gas on a surface of each wafer W of the holding area W2. Then, NH₃ gas is supplied from the reaction gas nozzle 53 and converted into plasma by the lower electrodes 16, so that active species are limitedly supplied only to the holding area W2. Accordingly, a molecular layer of SiN is formed on the surface of each wafer W of the holding area W2. During the supply of the NH₃ gas from the reaction gas nozzle 53, a purge gas may be supplied to the holding area W1 from the reaction gas nozzle 52. However, since the DCS in the surface of the wafer W in the holding area W1 is in a reaction-completed state and hence there is no remaining DCS capable of reacting with the active species supplied to the holding area W2, the purge gas may not be supplied.

A film forming cycle including the supply of the DCS gas, the supply of the active species of the NH₃ gas to the holding area W1, and the supply of the active species of the NH₃ gas to the holding area W2 is repeatedly performed plural times. Since the concentrations of the NH₃ gases supplied to the holding areas W1 and W2 are different from each other, SiN films having different film qualities can be formed in the holding areas W1 and W2 by repeatedly performing the film forming cycle. Specifically, it is possible to form SiN films which have, for example, different wet etching rates with respect to a predetermined liquid chemical. In this example, NH₃ gas having a high concentration is supplied to the holding area W1 which is more spaced apart from an exhaust port defined by an exhaust pipe 34 than the holding area W2. This is because a gas exhaust rate is lower at an upstream side when viewed from the exhaust port, i.e., a holding area side which is more distant from the exhaust port, so that it is possible to prevent the concentration of the supplied NH₃ gas from being lowered.

Instead of making the concentrations of the gases supplied from the reaction gas nozzles 52 and 53 different from each other, the time for which the gas is supplied in single film forming cycle, or the flow rates of the gas may be made different from each other, thereby forming SiN films having different film qualities. In this example, since the DCS gas only needs to be supplied to both the holding areas W1 and W2, the DCS gas may be supplied using a single nozzle which has ejection holes formed to cover the holding areas W1 and W2, as in the reaction gas nozzle 52 of the film forming apparatus 1.

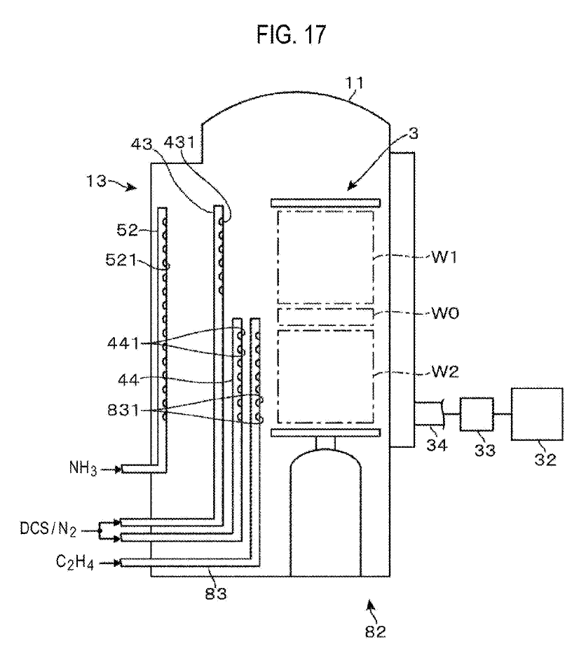

FIG. 17 illustrates the configuration of a film forming apparatus 82. The film forming apparatus 82 is different from the film forming apparatus 1 in that a gas nozzle 83 is further included. Ejection holes 831 of the gas nozzle 83 are formed to limitedly supply ethylene (C₂H₄) gas as a doping gas only to a holding area W2. In the film forming apparatus 82, the DCS gas is supplied to both the holding areas W1 and W2, for example. Then, along with the limited supply of the C₂H₄ gas only to the holding area W2, a purge gas is limitedly supplied only to the holding area W1 from the first nozzle 43. Accordingly, molecules of the C₂H₄ gas are adsorbed only to the wafer W in the holding area W2, and the adsorption of molecules is prevented in the holding area W1. Thereafter, the NH₃ gas converted into plasma is supplied to the holding areas W1 and W2. In the holding area W1, a molecular layer of SiN is formed. In the holding area W2, molecules of the DCS gas adsorbed onto the wafer W, the molecules of the C₂H₄ gas, and the NH₃ gas converted into plasma react with one another, thereby forming a molecular layer of SiCN. That is, a layer of the SiN doped with carbon is formed. Such a series of gas supply processes are repeatedly performed, so that a SiN film is formed on the wafer W of the holding area W1 and a SiCN film is formed on the wafer W of the holding area W2. In other words, films different from each other can be formed in the holding areas W1 and W2, respectively.

In the film forming apparatus 82, the C₂H₄ gas is supplied to the holding area W2 in a downstream side as viewed from the exhaust port implemented by the exhaust pipe 34, among the holding areas W1 and W2. With this configuration, the C₂H₄ gas supplied to the reaction vessel 11 is prevented from being diffused into the holding area W1 and thus exhausted. Accordingly, in the holding area W1, the formation of the SiCN film is more surely suppressed. It is desirable to form a film that requires more many kinds of gases in its formation in the holding area closer to the exhaust port as described above.

In the film forming apparatus 82, a nozzle for limitedly supplying the C₂H₄ gas only to the holding area W1 may be provided. Along with the limited supply of the C₂H₄ gas only to the holding area W2, the purge gas is limitedly supplied only to the holding area W1 from the first nozzle 43. Thereafter, before the NH₃ gas converted into plasma is supplied to the holding areas W1 and W2, the purge gas is limitedly supplied only to the holding area W2 from the first nozzle 43, along with the limited supply of the C₂H₄ gas only to the holding area W1. The concentrations of the C₂H₄ gases supplied to the holding areas W1 and W2, respectively, are different from each other. Accordingly, SiCN films having different doping quantity of carbon atoms may be formed on the wafer W of the holding area W1 and the wafer W of the holding area W2, respectively. The gases available in each embodiment are not limited to these examples. For example, a silicon oxide film may be formed using oxygen gas plasma and a silicon-based source gas.

### Evaluation Test

Evaluation tests performed in relation to the present disclosure will be described. As Evaluation Test 1, a film forming process was performed using the film forming apparatus 1. However, in Evaluation Test 1, the holding area W0 for the dummy wafers 10 was not defined in the wafer boat 3, and wafers W were disposed even in the middle slots of the wafer boat 3. That is, an upper portion of the area mentioned as the holding area W0 for the dummy wafers 10 in the foregoing description on the film forming apparatus 1 was included in the holding area W1 while a lower portion thereof being included in the holding area W2. A silicon wafer having an exposed surface was used as the wafer W. The film forming process was performed according to Steps S1 to S8. However, in the step corresponding to Step S2, the purge gas was supplied to the holding area W1 and the DCS gas was supplied to the holding area W2, instead of supplying the DCS gas to the holding area W1 while supplying the purge gas to the holding area W2. Thus, the thickness of a film on the wafer W of the holding area W2 became greater than that of a film on the wafer W of the holding area W1. In Evaluation Test 1 and later-described Evaluation Tests 2 and 3, the target thicknesses of films formed on the wafers W of the holding areas W1 and W2 were 30 angstroms (3 nm) and 50 angstroms (5 nm), respectively. After the film forming process, the thickness of a film on the wafer W in each slot was measured.

In Evaluation Test 2, in the same manner as Evaluation Test 1, a film forming process was performed with wafers W mounted in the wafer boat 3. The film forming process will be described using the sequences described in FIG. 11 and the like. The cycle including Sequences 1 to 3 was repeatedly performed plural times. The film forming cycle was performed only in the holding area W1 once in Sequences 1 and 2, and the film forming cycle was performed only in the holding area W2 once in Sequence 3. Unlike the film forming apparatus 1 used in Evaluation Test 1, the film forming apparatus 1 used in Evaluation Test 2 is not provided with the first tank 61 and the second tank 62. That is, the flow rate of the DCS gas supplied into the reaction vessel 11 is relatively small. Except these differences, Evaluation Test 2 was performed in the same manner as Evaluation Test 1.

In Evaluation Test 3, a process was performed in approximately the same manner as Evaluation Test 1. That is, the process was performed according to Steps S1 to S8 already described above. However, in order to make the thickness of the film on the wafer W of the holding area W2 greater than that in the holding area W1, the process was performed such that the purge gas was supplied to the holding area W1 and the DCS gas was supplied to the holding area W2 in the step corresponding to Step S2. In this step, the DCS gas was supplied to the reaction vessel 11 without passing through the second tank 62. In the step corresponding to Step S6, as in the above-described embodiment, the source gas was supplied into the reaction vessel 11 from the first nozzle 43 and the second nozzle 44 through the first tank 61 and the second tank 62. Except these differences, Evaluation Test 3 was performed in the same manner as Evaluation Test 1.

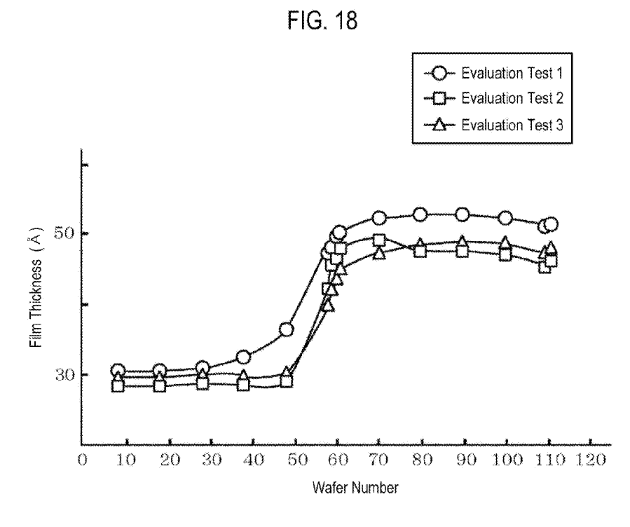

The graph of FIG. 18 illustrates test results of Evaluation Tests 1 to 3. The horizontal axis of the graph represents a wafer W number, wherein as the wafer W number becomes smaller, the wafer W is disposed and processed in a slot at an upper end in the wafer boat 3. The vertical axis of the graph represents the film thickness (unit: angstrom). As shown in the graph, the thicknesses of films on wafers W numbered as 1 to 40 in Evaluation Tests 1 to 3 were about 30 angstroms that is a target film thickness. In addition, the thicknesses of films on wafers W numbered as 75 to 100 in Evaluation Tests 1 to 3 were about 50 angstroms that is a target film thickness. That is, it has been confirmed that the thicknesses of films formed on the wafers W at an upper portion and a lower portion of the wafer boat 3, respectively, can be individually controlled. From the results of Evaluation Tests 1 to 3, the present inventors have obtained the knowledge that leads to the present disclosure.

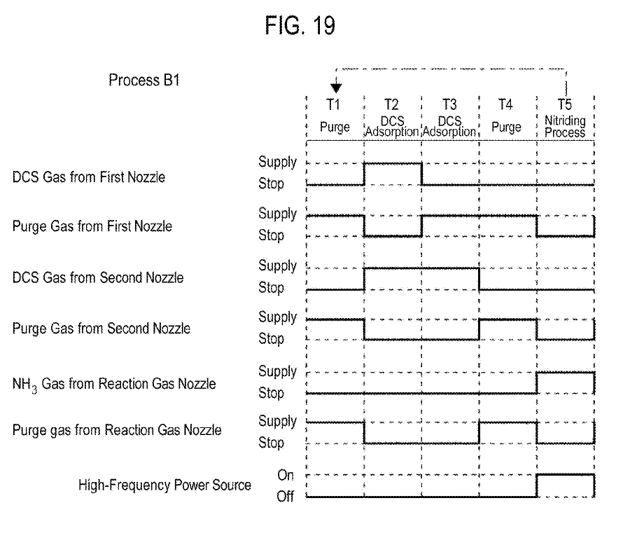

Next, another example of the process using the film forming apparatus 1 will be described, focusing on differences between this process and the process described in FIG. 5, with reference to FIG. 19 that shows a timing chart representing a state of supplying/stopping various kinds of gases, and a state of turning on/off the high-frequency power source 17, as does FIG. 5. In the process shown in FIG. 19 (referred to as “Process B1” for convenience of illustration), as described in FIGS. 1 and 3, a group of wafers W, dummy wafers 10, and another group of wafers W are mounted in the holding areas W1, W0, and W2 in the wafer boat 3, respectively. For convenience of illustration, the wafers held in the holding areas W1 and W2 are designated by C1 and C2, respectively. A pattern is finely and densely formed on a surface of the wafer C2, as compared with a surface of the wafer C1, so that the surface area of the wafer C2 is greater than that of the wafer C1.

Hereinafter, sequences of Process B1 will be described. First, if the wafer boat 3 in which the wafers C1 and C2 and the dummy wafers 10 are mounted is loaded into the reaction vessel 11 as already described above, the N₂ gas (purge gas) is supplied from the first nozzle 43, the second nozzle 44, and the reaction gas nozzle 52, so that the inside of the reaction vessel 11 is purged (Step T1). Then, after the supply of the purge gas from each of the nozzles 43, 44, and 52 is stopped, the DCS gas is respectively supplied to the holding areas W1 and W2 from the first nozzle 43 and the second nozzle 44, so that molecules of the DCS gas are adsorbed onto the surfaces of the wafers C1 and C2 (Step T2). In Process B1, the DCS gas is supplied from the gas nozzles 43 and 44 at the same flow rate.

After the supply of the DCS gas to the holding area W1 from the first nozzle 43 is stopped, the N₂ gas (purge gas) is supplied from the first nozzle 43. Meanwhile, the DCS gas is continuously supplied to the holding area W2 from the second nozzle 44. That is, the DCS is limitedly supplied only to the wafer C2, so that molecules of the DCS gas are continuously adsorbed onto the wafer C2 (Step T3). Thereafter, the supply of the DCS gas from the second nozzle 44 is stopped, and the N₂ gas is supplied from the second nozzle 44 and the reaction gas nozzle 52. The N₂ gas is also continuously supplied from the first nozzle 43, so that the DCS gas in the reaction vessel 11 is purged (Step T4).

Thereafter, the supply of the N₂ gas from each of the nozzles 43, 44, and 52 is stopped. Subsequently, the NH₃ gas is supplied from the reaction gas nozzle 52 and simultaneously the high-frequency power source 17 is turned on, so that plasma is generated and active species of the NH₃ gas are generated. The active species are supplied to the wafers C1 and C2 to nitride the adsorbed DCS, and a molecular layer of SiN is formed on the surface of each of the wafers C1 and C2 (Step T5). Then, the supply of the NH₃ gas is stopped, and simultaneously, the high-frequency power source 17 is turned off, so that the formation of the plasma is stopped. Thereafter, Steps T1 to T5 are repeatedly performed a predetermined repetition number, and molecular layers of SiN are laminated on each of the wafers C1 and C2, thereby forming a SiN film.

As described above, in Process B1, the apparatus 1 is operated such that the flow rates of the DCS gases supplied to the holding areas W1 and W2, respectively, are equal to each other, and the DCS gas is supplied to the wafer C2 of the holding area W2 for a longer time as compared with the wafer C1 of the holding area W1. Thus, with respect to the wafer C2 having a larger surface area, it is possible to prevent the lack of the amount of the DCS gas supplied from a side of the wafer C2. That is, it is possible to prevent the amount of molecules of the DCS gas adsorbed onto a central portion of the wafer C2 from getting smaller than that onto a peripheral portion of the wafer C2. As a result, films can be formed on each of the wafers C1 and C2 such that the deterioration of in-plane uniformity of the film thickness is suppressed. In Process B1, the thicknesses of the SiN films formed on the wafers C1 and C2, respectively, may be equal to or different from each other.

In order to prevent the adsorption amount of the DCS gas onto the central portion of the wafer C2 from getting small, it may be considered that a single gas nozzle having ejection holes formed to cover both the holding areas W1 and W2 is installed and that a relatively large amount of DCS gas is supplied to the gas nozzle such that the DCS gas is supplied to the holding areas W1 and W2 at the same flow rate for the same duration. That is, it may be considered that a large amount of DCS gas may be uniformly supplied to the holding areas W1 and W2. However, as already described above, when the ALD is performed, the DCS gas that is the source gas is adsorbed onto the surface of the wafer W and, in a practical process, the adsorption amount of the DCS gas is not saturated but varies depending on the amount of the DCS gas supplied to the wafer W. That is, even in performing the ALD, as in the chemical vapor deposition (CVD), a film is formed to have a thickness corresponding to the supply amount of the source gas. If a large amount of DCS gas is uniformly supplied to the holding areas W1 and W2 as described above, the thickness of the SiN film formed on the wafer C1 may be excessively increased. In this regard, Process B1 has effectiveness in increasing the in-plane uniformity of the thickness of the wafer C2 and forming SiN films having an appropriate thickness on the wafers C1 and C2. Like the case of the process of FIG. 5, even when a film is formed in Process B1, the production efficiency of the film forming apparatus 1 can be improved as compared with when the wafers C1 and C2 are individually processed, and the number of necessary dummy wafers 10 can be reduced.

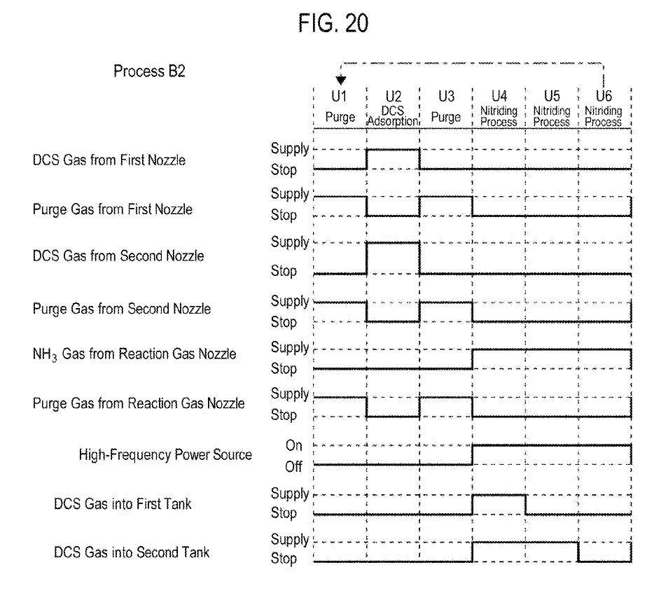

Next, another process example using the film forming apparatus 1 will be described, focusing on differences between this process and Process B1 of FIG. 19, with reference to the timing chart of FIG. 20. As in the Process B1 of FIG. 19, the wafers C1 and C2 and the dummy wafers 10 are disposed in the wafer boat 3 in the process shown in FIG. 20 (referred to as “Process B2”). FIG. 20 shows timings at which a gas is supplied into the first tank 61 and the second tank 62 storing DCS gas or the gas supply is stopped, in addition to timings at which the gas is supplied from each gas nozzle or the gas supply is stopped and timings at which the high-frequency power source 17 is turned on/off.

Hereinafter, sequences of Process B2 will be described. First, the wafer boat 3 having the wafers mounted therein is loaded into the reaction vessel 11, and the supply of the DCS gas into the first tank 61 and the second tank 62 is started. The supply of the DCS gas into the second tank 62 is continued even after the supply of the DCS gas into the first tank 61 is stopped, so that a larger amount of the DCS gas is stored in the second tank 62, as compared with the first tank 61. Accordingly, the pressure in the second tank 62 becomes higher than that in the first tank 61.

Then, the N₂ gas is supplied from the first nozzle 43, the second nozzle 44, and the reaction gas nozzle 52, so that the inside of the reaction vessel 11 is purged (Step U1). Thereafter, the supply of the purge gas from each of the gas nozzles 43, 44, and 52 is stopped, and the DCS gas is supplied to the first nozzle 43 and the second nozzle 44 from the first tank 61 and the second tank 62, respectively. On the other hand, for the valves V14 and V23 interposed between the N₂ gas supply source 7 and the respective nozzles 43 and 44 (see FIG. 4), the opening degree of the valve V14 is set to be greater than that of the valve V23, so that a larger amount of the N₂ gas is supplied to the first nozzle 43 as compared with the second nozzle 44. In this manner, the DCS gas and the N₂ gas supplied to the gas nozzles 43 and 44 are supplied to the holding areas W1 and W2 (Step U2).

As described above, since the DCS gas is stored in the tanks 61 and 62 such that the pressure in the tank 62 is higher than that in the tank 61, the flow rate of the DCS gas supplied from the second nozzle 44 is greater than that of the DCS gas supplied from the first nozzle 43. Thus, the DCS gas is supplied at a relatively high flow rate to the wafer C2 having a relatively large surface area, so that the DCS gas uniformly spreads in not only the peripheral portion but also the central portion of the wafer C2. Thus, molecules of the DCS gas are adsorbed onto the surface of the wafer C2 with high in-plane uniformity.

Since an N₂ gas as a pressure adjustment gas is supplied to the first nozzle 43 from the gas supply source 7 at a flow rate relatively larger than that of the second nozzle 44, the difference between the total flow rate of the gas ejected from the first nozzle 43 and the total flow rate of the gas ejected from the second nozzle 44 is reduced. As a result, the pressure in the holding area W1 and the pressure in the holding area W2 become equal to each other, for example. Thus, pressure distribution in the holding areas W1 and W2 is adjusted in this manner, so that it is possible to prevent an accident that the DCS gas supplied from the second nozzle 44 is supplied to the holding area W1 due to the disturbance of the gas flow in the reaction vessel 11. For example, (total flow rate of gas ejected to holding area W1 from first nozzle 43)/(total flow rate of gas ejected to holding area W2 from second nozzle 44) ranges from 0.85 to 1.15.

Thereafter, the supply of the DCS gas from the gas nozzles 43 and 44 is stopped and the N₂ gas is supplied from the gas nozzles 43, 44, and 52, so that the DCS gas in the reaction vessel 11 is purged (Step U3). Then, the supply of the N₂ gas from each of the gas nozzles 43, 44, and 52 is stopped, and NH₃ gas is supplied from the reaction gas nozzle 52 and simultaneously the high-frequency power source 17 is turned on, so that plasma is generated. The DCS gas in the surfaces of the wafers C1 and C2 are nitrided by active species of the NH₃ gas, so that a molecular layer of SiN is formed (Step U4). While the nitriding process as described above is performed, the DCS gas is supplied and stored in the first tank 61 and the second tank 62.

Thereafter, the supply of the DCS gas into the first tank 61 is stopped while the supply of the DCS gas into the second tank 62 is continued (Step U5). Then, the supply of the DCS gas into the second tank 62 is also stopped. Thus, a larger amount of the DCS gas is stored in the second tank 62 than the first tank 61, and the pressure in the second tank 62 becomes higher than that in the first tank 61 (Step U6). Then, the supply of the NH₃ gas from the reaction gas nozzle 52 is stopped and simultaneously the high-frequency power source 17 is turned off, so that the generation of the plasma is stopped. Thereafter, Steps U1 to U6 are repeatedly performed for a predetermined repetition number, and molecular layers of SiN are laminated on each of the wafers C1 and C2, thereby forming a SiN film. The effects described in Process B1 can be also obtained in Process B2 of FIG. 20. In this example, although the first nozzle 43 is configured as a gas supply unit for pressure adjustment, a gas nozzle for supplying an N₂ gas to the holding area W1 may be installed as a gas supply unit for pressure adjustment, separately from the first nozzle 43.

When Processes B1 and B2 are performed, wafers W having the same surface area may be mounted in the holding areas W1 and W2. In this case, SiN films having different thicknesses may be formed on the wafers W in the holding areas W1 and W2, respectively. Since, even in the case where the wafers C1 and C2 are mounted in the respective holding areas W1 and W2 in the process shown in FIG. 5, the holding area W1 is supplied with a larger amount of the DCS gas than the holding area W2 while Steps S1 to S8 are performed, films can be also formed with high in-plane uniformity on each of the wafers C1 and C2, as in the Processes B1 and B2. However, since the number of times the purging is performed inside the reaction vessel can be reduced in Processes B1 and B2 as compared with the process of FIG. 5, the Processes B1 and B2 are preferable in some embodiments.

The configurations of the film forming apparatuses and the methods for forming a film already described above may be combined with each other. For example, Processes B1 and B2 of FIGS. 19 and 20 may be performed in the film forming apparatus 81 in which the active species of the NH₃ gas can be individually supplied to the holding areas W1 and W2 as described in FIG. 16, so that SiN films having different film qualities may be formed on the wafers C1 and C2, respectively. Alternatively, Processes B1 and B2 may be performed in the film forming apparatus 82 in which the ethylene gas can be limitedly supplied only to the holding area W2 as described in FIG. 17, so that SiN films having different film qualities may be formed on the wafers C1 and C2, respectively.

According to the present disclosure, while a source gas is supplied to one of a first substrate holding area and a second substrate holding area in a state in which the first substrate holding area and the second substrate holding area are divided by substrates for division, a purge gas is supplied to the other substrate holding area. According to another embodiment of the present disclosure, the source gases are respectively supplied at different flow rates to the first substrate holding area and the second substrate holding area, and simultaneously, a gas for adjusting the pressure distribution in the substrate holding areas is supplied to the second substrate holding area. With this configuration, since the processes can be individually performed on the substrates in the first substrate holding area and the substrates in the second substrate holding area, respectively, films having different film thicknesses, different film qualities or different kinds can be formed. Further, the film forming can be performed at the same time even on substrates having different surface areas. Thus, many substrates can be mounted in a substrate holding unit when performing the process, thereby improving the productivity of the apparatus.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus in which a film is formed by alternately supplying a source gas and a reaction gas reacting with the source gas to generate a reaction product into a vertical reaction vessel having a substrate holding part disposed therein, the substrate holding part holding a plurality of substrates in a form of a shelf, the film forming apparatus comprising:
a first source gas supply part and a second source gas supply part configured to limitedly supply the source gas only to a first substrate holding area and a second substrate holding area, respectively, among the first substrate holding area and the second substrate holding area disposed along an arrangement direction in which the substrates are arranged in the substrate holding part;
a reaction gas supply part configured to supply the reaction gas to the first substrate holding area and the second substrate holding area;
a purge gas supply part configured to supply a purge gas for preventing the source gas supplied to one of the first substrate holding area and the second substrate holding area from being supplied to the other substrate holding area;
a division-purpose substrate held between the first substrate holding area and the second substrate holding area in the substrate holding part to divide the substrate holding part into the first substrate holding area and the second substrate holding area; and
a control part configured to output a control signal such that a first cycle including supplying the source gas to the first substrate holding area and supplying the reaction gas to the first substrate holding area and a second cycle including supplying the source gas to the second substrate holding area and supplying the reaction gas to the second substrate holding area are each performed plural times.

2. The film forming apparatus of claim 1, wherein the control part outputs a control signal such that the first cycle and the second cycle are performed different numbers of times from each other.

3. The film forming apparatus of claim 1, wherein, when a second cycle repetition number of the second cycle required in one process is larger than a first cycle repetition number of the first cycle required in the one process, the control part outputs a control signal to perform a step of performing the first cycle for the first cycle repetition number and a step of performing the second cycle for the second cycle repetition number before or after the step of performing the first cycle.

4. The film forming apparatus of claim 1, wherein, when a second cycle repetition number of the second cycle required in one process is larger than a first cycle repetition number of the first cycle required in the one process, the control part outputs a control signal to perform a step of simultaneously performing the first cycle and the second cycle for the first cycle repetition number and a step of performing the second cycle for the number of times obtained by subtracting the first cycle repetition number from the second cycle repetition number.

5. The film forming apparatus of claim 1, wherein, when a second cycle repetition number of the second cycle required in one process is larger than a first cycle repetition number of the first cycle required in the one process, the control part outputs a control signal to perform a step of repeating a cycle set plural times, the cycle set including a series of processes of performing the first cycle and performing the second cycle before or after performing the first cycle, and
wherein the number of times the first cycle is performed and the number of times the second cycle is performed in each cycle set are determined by dividing the first cycle repetition number and the second cycle repetition number by the number of times the cycle set is repeated, respectively, and the number of times the second cycle is repeated in each cycle set is greater than that of the first cycle in each cycle set.

6. The film forming apparatus of claim 1, wherein, when a second cycle repetition number of the second cycle required in one process is larger than a first cycle repetition number of the first cycle required in the one process, the control part outputs a control signal to perform a step of repeating a cycle set plural times, a cycle set including a series of processes of performing the first cycle and the second cycle and performing the second cycle without performing the first cycle before or after performing the first cycle and the second cycle, and
wherein the number of times the first cycle is performed and the number of times the second cycle is performed in each cycle set are determined by dividing the first cycle repetition number and the second cycle repetition number by the number of times the cycle set is repeated, respectively.

7. The film forming apparatus of claim 1, wherein a first period for which supplying the source gas is performed in the first cycle including supplying the source gas to the first substrate holding area and supplying the reaction gas to the first substrate holding area, overlaps with a second period for which supplying the source gas is performed in the second cycle including supplying the source gas to the second substrate holding area and supplying the reaction gas to the second substrate holding area, and the second period is longer than the first period, and
wherein the control part outputs a control signal such that the purge gas is supplied to the first substrate holding area during a period which is included in the second period but not included in the first period.

8. The film forming apparatus of claim 1, wherein kinds of the source gases supplied from the first source gas supply part and the second source gas supply part are different from each other.

9. The film forming apparatus of claim 8, wherein a main source gas and a doping gas containing an element with which a reaction product of the main source gas and the reaction gas is doped are supplied from one of the first source gas supply part and the second source gas supply part, and the main source gas is supplied from the other source gas supply part, and
wherein the purge gas supply part supplies the purge gas to prevent the doping gas supplied to one of the first substrate holding area and the second substrate holding area from being supplied to the other substrate holding area.

10. A film forming apparatus in which a film is formed by alternately supplying a source gas and a reaction gas reacting with the source gas to generate a reaction product into a vertical reaction vessel having a substrate holding part disposed therein, the substrate holding part holding a plurality of substrates in a form of a shelf, the film forming apparatus comprising:
a first reaction gas supply part and a second reaction gas supply part configured to limitedly supply the reaction gas only to a first substrate holding area and a second substrate holding area, respectively, among the first substrate holding area and the second substrate holding area disposed along an arrangement direction in which the substrates are arranged in the substrate holding part;
a source gas supply part configured to supply the source gas to the first substrate holding area and the second substrate holding area;
a purge gas supply part configured to supply a purge gas for preventing the reaction gas supplied to one of the first substrate holding area and the second substrate holding area from being supplied to the other substrate holding area;
a division-purpose substrate held between the first substrate holding area and the second substrate holding area in the substrate holding part to divide the substrate holding part into the first substrate holding area and the second substrate holding area; and
a control part configured to output a control signal such that a first cycle including supplying the source gas to the first substrate holding area and supplying the reaction gas to the first substrate holding area and a second cycle including supplying the source gas to the second substrate holding area and supplying the reaction gas to the second substrate holding area are each performed plural times.

11. A film forming apparatus in which a film is formed by alternately supplying a source gas and a reaction gas reacting with the source gas to generate a reaction product into a vertical reaction vessel having a substrate holding part disposed therein, the substrate holding part holding a plurality of substrates in a form of a shelf, the film forming apparatus comprising:
a first source gas supply part configured to limitedly supply the source gas at a first flow rate only to a first substrate holding area, among the first substrate holding area and a second substrate holding area disposed along an arrangement direction in which the substrates are arrange in the substrate holding part;
a second source gas supply part configured to supply the source gas at a second flow rate greater than the first flow rate only to the second substrate holding area, in parallel with the supply of the source gas from the first source gas supply part;
a gas supply part for pressure adjustment configured to supply a pressure adjustment gas for adjusting a pressure distribution in the first substrate holding area and the second substrate holding area to the first substrate holding area when the source gas is supplied to the first substrate holding area and the second substrate holding area;
a division-purpose substrate held between the first substrate holding area and the second substrate holding area in the substrate holding part to divide the substrate holding part into the first substrate holding area and the second substrate holding area; and
a control part configured to output a control signal such that a cycle including supplying the source gas to the first substrate holding area and supplying the reaction gas to the first substrate holding area and a cycle including supplying the source gas to the second substrate holding area and supplying the reaction gas to the second substrate holding area are each performed plural times.

12. The film forming apparatus of claim 7, wherein the first substrate holding area is an area in which first substrates are held, and the second substrate holding area is an area in which second substrates having a surface area greater than that of the first substrates are held.
